(19) United States
(12) Patent Application Publication
(10) Pub. No.: US 2025/0223687 A1
(43) Pub. Date: Jul. 10, 2025

(54) METHOD FOR COATING A TOOL PART OF A MACHINING TOOL

(71) Applicant: Hartmetall-Werkzeugfabrik Paul Horn GmbH, Tuebingen (DE)

(72) Inventor: Dominic Diechle, Weil im Schoenbuch (DE)

(21) Appl. No.: 19/093,906

(22) Filed: Mar. 28, 2025

Related U.S. Application Data
(63) Continuation of application No. PCT/EP2023/073545, filed on Aug. 28, 2023.

(30) Foreign Application Priority Data
Sep. 29, 2022 (DE) 10 2022 125 083.0

(51) Int. Cl. C23C 14/35; B23B 27/14; C23C 14/00; C23C 14/08

(52) U.S. Cl. CPC C23C 14/35; B23B 27/148; C23C 14/0036; C23C 14/081; B23B 2222/28; B23B 2224/04; B23B 2224/24; B23B 2224/28; B23B 2228/08; B23B 2228/105; B23B 2228/36

(57) ABSTRACT

A method of producing a coated tool part of a cutting tool. The tool part is coated with a coating containing at least one aluminum oxide (Al₂O₃) containing Al₂O₃-layer having an alpha-Al₂O₃ phase fraction and a gamma-Al₂O₃ phase fraction. The at least one Al₂O₃-layer is produced using a reactive magnetron sputtering process.

### CROSS REFERENCE TO RELATED APPLICATIONS

This application is a continuation of international patent application PCT/EP2023/073545, filed on Aug. 28, 2023 designating the U.S., which international patent application has been published in German language and claims priority from German patent application DE 10 2022 125 083.0, filed on Sep. 29, 2022. The entire contents of these priority applications are incorporated herein by reference.

### FIELD

This disclosure relates to a method of producing a coated tool part of a cutting tool. This disclosure further relates to a coated tool part of a machining tool.

The herein presented method may be used to produce a tool coating comprising at least one layer comprising aluminum oxide (Al₂O₃). This aluminum oxide layer is referred to below as Al₂O₃-layer.

Such an Al₂O₃-layer can consist entirely of Al₂O₃ or also comprise other components in addition to Al₂O₃, for example admixtures of other metals or metal oxides and/or proportions of impurities.

### BACKGROUND

Today, the production of innovative coatings is a core competence in industrial tool manufacturing for metal machining. Due to the constantly growing requirements with regard to the possible applications, cutting speeds and service life of such machine tools, which are generally referred to as cutting tools, the demands on the aforementioned tool coatings are also increasing.

Al₂O₃-coatings, i.e. coatings comprising at least one layer containing Al₂O₃, are very suitable for the aforementioned applications due to their material properties. Therefore, according to the prior art, such Al₂O₃-coatings are already used in a variety of ways for coating cutting tools.

Al₂O₃ has several phases. Alpha aluminum oxide (α-Al₂O₃) refers to the rhombohedral thermodynamically stable Al₂O₃-phase. The thermodynamically stable α-Al₂O₃-phase is the high-temperature phase of aluminum oxide. This phase is described by the space group R-3c and is referred to as corundum. In addition to the α-Al₂O₃-phase, there are a number of metastable Al₂O₃-phases, such as the kappa aluminum oxide phase (κ-Al₂O₃) or the gamma aluminum oxide phase (γ-Al₂O₃). The disadvantage of these metastable Al₂O₃-phases is that they transform into the thermodynamically stable α-Al₂O₃-phase at higher temperatures. The metastable Al₂O₃-phases transform into the α-Al₂O₃-phase either directly or in the form of different transformation sequences.

The transformation temperatures depend on the purity, the grain size and, for example, the thermodynamic pre-treatment of the materials. These transformation processes limit the maximum operating temperature of the metastable Al₂O₃-phases in machining applications.

In the literature as well as in industrial applications, both the metastable Al₂O₃-phases and the thermodynamically stable-Al₂O₃-phase are used according to prior art.

The α-Al₂O₃-phase is according to the prior art typically deposited using chemical vapor deposition (CVD). Such CVD coatings usually have a high proportion of α-Al₂O₃ in the Al₂O₃-layer. The Al₂O₃ coatings produced using CVD offer effective wear protection in classic turning applications. A disadvantage of these CVD-Al₂O₃-coatings is the high residual tensile stresses. CVD coatings are also deposited at temperatures of typically 1000° C. to 1100° C. These high coating temperatures lead to embrittlement of the tools.

Alternatively, plasma-assisted CVD processes are used to produce the α-Al₂O₃-phase at a reduced deposition temperature. This CVD process also requires elevated temperatures of 800° C., for example, and incorporates disadvantageous chlorine residues from the carrier gas into the coating. The CVD coatings with α-Al₂O₃ typically have a very high layer thickness of 20 μm. Another disadvantage is the large amount of rounding required on the cutting edges of the tools due to the relatively high coating thicknesses together with the complex residual stress states.

Alternatively, Al₂O₃-coatings produced by physical vapor deposition (PVD) are currently used in metal cutting (see, for example, EP 1 762 637 B1). These Al₂O₃-coatings are used for metal cutting in combination with other coatings containing nitrides and/or carbides in the form of a multilayer coating. These coatings have sufficient toughness, but at the same time a disadvantageous, insufficient temperature and oxidation resistance at very high cutting speeds. Thus, these materials have their limits.

In a PVD sputtering process, the starting material is converted into the gas phase by sputtering. The particles released from the so-called target, predominantly atoms and ions, are accelerated by an energy input onto the substrate to be coated and are deposited on the surface of the substrate as a coating. The material to be deposited, i.e. the target material, is usually present as a solid in a PVD process and is located in an evacuated coating chamber, also known as a reaction chamber. In this reaction chamber, the substrate to be coated is spatially separated from the target. Depending on the type of PVD process, not only one target but also two or more targets are used.

The targets are connected to power supply units. Energy is typically applied to the target using a plasma and an electric field. The reaction chamber is filled with an inert process gas, which is brought into an ionized state by the energy input of the electric field (plasma formation). The charged process gas ions are accelerated in the direction of the target(s) by the electric field and knock atoms and ions of the target material out of its surface through this “bombardment”, i.e. through physical impulse transfer. This atomized target material then moves in the direction of the substrate, resulting in a coating on its surface.

In reactive PVD processes, a reactive gas is also used in the reaction chamber, which) in the case of an Al₂O₃-coating typically contains oxygen (O₂) and/or a nitrogen oxide (NOₓ). The nitrogen oxide can be, for example, dinitrogen monoxide (N₂O), nitrogen monoxide (NO), nitrogen dioxide (NO₂) and/or dinitrogen tetroxide (N₂O₄).

The following subgroups of PVD processes are typically used in the PVD processes that are used in machining technology to produce tool coatings: Arc processes, also known as arc PVD, and sputtering processes. The sputtering processes include the direct current (DC) sputtering process or the high-power impulse magnetron sputtering process (HiPIMS). In the field of tool coatings, the preferred sputtering process is magnetron sputtering. In the latter magnetron sputtering process, a magnetic field is generated behind the target by one or more electromagnets or permanent magnets in addition to the electric field between the cathode and anode.

The deposition of Al₂O₃-coatings using DC sputtering processes is not possible due to the electrical insulation of Al₂O₃. Arc processes are also not suitable for the deposition of industrial Al₂O₃-coatings on cutting tools due to the massive formation of macro-droplets.

Al₂O₃-coatings that are deposited using the dual magnetron sputtering process are known from the prior art (see WO 2019/092009 A1). In dual magnetron sputtering (DMS) technology, two targets are connected to each other via a power supply network. During the deposition process, the two targets act alternately as anode and cathode, enabling the deposition of electrically insulating coatings such as Al₂O₃.

However, in the method known from WO 2019/092009 A1, an Al₂O₃-coating is deposited in the γ-Al₂O₃-phase. A disadvantage of these γ-Al₂O₃-coatings, in addition to a relatively low modulus of elasticity, is their limited temperature stability above typically 900° C. As already mentioned, the metastable cubic γ-Al₂O₃-phase transforms under such conditions into the thermodynamically stable rhombohedral α-Al₂O₃-phase (corundum, known for example from PDF No. 42-1468 of the ICDD database). This phase transformation is typically associated with a massive loss of coating hardness and is therefore detrimental to the cutting performance of a tool. γ-Al₂O₃-coatings exhibit hardness values in the range of approx. 3000 HV to 3500 HV and reduced modulus of elasticity values in the range of 350 GPa to 370 GPa (see WO 2019/092009 A1).

WO 2020/094718 A1 also discloses a method of producing an Al₂O₃-coating, which is deposited using a HiPIMS process. The Al₂O₃-coating deposited in this process has both α-Al₂O₃-phase fractions and γ-Al₂O₃-phase fractions.

### SUMMARY

It is an object to provide a method of producing a coated tool part of a cutting tool, with which an Al₂O₃-coating can be produced which has advantageous properties compared to the Al₂O₃-coatings which are produced using the aforementioned processes/methods from the prior art. The disadvantageous high-temperature stability of the PVD-γ-Al₂O₃-coatings with their relatively low modulus of elasticity values is to be avoided, as is the embrittlement of the tools during coating with CVD-α-Al₂O₃-coatings, which exhibit the disadvantageous tensile residual stresses described.

According to a first aspect, a method is presented, comprising:
providing the tool part as a substrate comprising a substrate material selected from the group consisting of cemented carbide, cermet, cubic boron nitride (CBN), polycrystalline diamond (PCD) or high speed steel; and
coating the tool part with a coating comprising at least one aluminum oxide (Al₂O₃) containing Al₂O₃-layer having an alpha-Al₂O₃ phase fraction and a gamma-Al₂O₃ phase fraction, wherein the at least one Al₂O₃-layer is produced by means of a reactive magnetron sputtering process, and wherein in the reactive magnetron sputtering process:
   at least one aluminum target is used;
   a gas mixture is used which has a noble gas as a first component and oxygen (O₂) and/or a nitrogen oxide (NOₓ) as a second component as a reactive gas;
   a total gas pressure <1 Pa is set;
   a process temperature between 400° C. and 650° C. is set;
   a maximum target power density≤100 W/cm² and a maximum target current≤200 A is set;
   a magnetic field is generated using at least one solenoid coil, which is operated with a coil current ≥7 A.

According to a second aspect, a coated tool part of a cutting tool is presented, the tool part comprising a substrate material selected from the group consisting of cemented carbide, cermet, cubic boron nitride (CBN), polycrystalline diamond (PCD) or high-speed steel, and a coating comprising at least one aluminum oxide-containing Al₂O₃-layer having an α-Al₂O₃-phase fraction and a γ-Al₂O₃-phase fraction, wherein the at least Al₂O₃-layer is produced by means of the aforementioned method.

With the presented method, an Al₂O₃-coating with very positive machining properties may be produced, which has a comparatively high α-Al₂O₃-phase fraction and a variable γ-Al₂O₃-phase fraction. This is achieved in particular through a suitable selection of the process parameters used, such as total gas pressure, process temperature, maximum target power density, maximum target current and coil current for generating the magnetic field.

It is also advantageous that the technically established and controllable reactive magnetron sputtering process is used for this purpose. The method can therefore be implemented on conventional industrial plants for production in large batches. In addition, in contrast to an arc process, the formation of macro-droplets of metallic particles can be completely or at least almost completely avoided.

Furthermore, it has been found that the method can be used to produce Al₂O₃-coatings that have comparatively high hardness values of H_{IT}≥20 GPa and a comparatively high value for the instrumented modulus of elasticity E_{IT}≥350 GPa.

Compared to the method disclosed in WO 2019/092009 A1, the method is carried out in particular at a lower total gas pressure of <1 Pa. In addition, the coil current used to generate the magnetic field is selected to be significantly higher with values ≥7 A.

Compared to the method disclosed in WO 2020/094718 A1, a significant difference in the herein presented method is that the reactive magnetron sputtering process is not designed as a HiPIMS method. This is particularly evident from the selected parameters, namely the maximum target power density of ≤100 W/cm² and the maximum target current of ≤200 A.

According to a refinement, the reactive magnetron sputtering process used in the method is a pulsed magnetron sputtering process.

In other words, the electric field required for the magnetron sputtering process is preferably generated using a time sequence of individual voltage pulses. The voltage pulses can be sinusoidal, triangular or rectangular, for example. According to a refinement, the voltage pulses are configured as rectangular voltage pulses.

According to a further refinement, the voltage pulses are bipolar voltage pulses. Bipolar rectangular voltage pulses have proven to be particularly advantageous compared to a bipolar sinusoidal voltage curve in the method

According to a refinement, the voltage pulses have a pulse frequency in the range from 10 KHz to 150 kHz. According to a further refinement, the voltage pulses have a pulse frequency in the range from 40 KHz to 80 KHz. The pulse frequency preferably remains constant during the process.

According to a refinement, an operating point is set for each target as part of the process control via the oxygen gas flow supplied. A separate oxygen inlet is provided for each target. Depending on the amount of oxygen supplied via the oxygen inlet, the operating point can be set using automated process control. The operating point refers to a time-averaged voltage at the target.

According to a further refinement, the reactive magnetron sputtering process is a dual magnetron sputtering process which has two targets which are connected to each other via a bipolar power supply, the two targets acting alternately as anode and cathode.

Although it is sufficient if one of the two targets is an aluminum target (for example, the other target can have a further/other metal or metal mixture), it is advantageous for the production of the Al₂O₃-coating if the reactive magnetron sputtering process is a dual magnetron sputtering process with two pure aluminum targets.

The total gas pressure prevailing in the reaction chamber, which is composed of the partial pressures of the components of the gas mixture (noble gases on the one hand and oxygen and/or nitrogen oxides or nitrogen on the other), may be set to <700 mPa.

According to a further refinement, the coil current for generating the magnetic field is selected to be ≤10 A. The coil current is therefore preferably in the range of 7 A to 10 A.

It should be noted at this point that the phrase “from X to Y” and the phrase “between X and Y” refer to value ranges that include both the stated lower limit (X) and the stated upper limit (Y). This applies not only to the last-mentioned coil current, but also to all other parameters mentioned herein.

With regard to the system for generating the magnetic field required for the magnetron sputtering process, the following should be mentioned in particular: The magnetic field is preferably generated by means of permanent magnets and at least one magnetic coil, which are arranged behind the at least one target. The distance between the permanent magnets and the targets is preferably adjustable. For example, the permanent magnets can be moved automatically via a drive system. It has been found that in order to produce the Al₂O₃-layers, the permanent magnets are preferably permanently arranged in their foremost position closest to the target. Furthermore, the magnet system can have magnetic plates with an SNS or NSN orientation in different thicknesses. Furthermore, the magnet system has a single coil or a plurality of electrical coils, preferably at least four coils. Each of these coils is connected to its own DC power supply unit. The aforementioned coil current can be specified and set at each of the power supply units. Preferably, the polarity of the output voltage of each power supply unit can be set separately. This polarity leads to a coil current in SNS or NSN orientation. It is preferred that two of the four coils mentioned are in operation. The power supply units of the two remaining coils are preferably switched off. The above-mentioned coil current refers in each case to the coils that are switched on.

Ultimately, therefore, there is a superposition of the magnetic fields generated by the coils and the permanent magnets. The deposition of the coating is influenced by a combination of the magnetic fields of the permanent magnets and the magnetic fields of the coils. The number of windings of the coils can be 800 per coil, for example.

According to a further refinement, a time-averaged target power density of 3 W/cm² to 30 W/cm², preferably from 4 W/cm² to 20 W/cm², is set for the reactive magnetron sputtering process.

The time-averaged power density at the target (referred to here as target power density) is calculated by averaging the power at at least one target over time and the size of the area of the at least one target. In the case of the dual magnetron sputtering process (DMS) with an output power of the DMS power supply of, for example, 20 KW and two targets with a size of, for example, 83 cm×17 cm, the time-averaged power density is calculated as follows: 20 kW÷2÷83 cm÷17 cm=7.09 W/cm².

The maximum power density at the target is calculated using the time-averaged power at at least one target, the fill factor D and the size of the area of the at least one target. The fill factor D is the ratio between pulse duration and repetition interval. The repetition interval is the time interval from the start of a pulse at a target to the start of the next pulse at the same target. For an exemplary frequency of 40 kHz, the repetition interval is 1/(40 kHz)=25 μs. In the case of an exemplary pulse duration of 12.5 μs, the fill factor at a frequency of 40 KHz is correspondingly 12.5 μs/25 μs=0.5. In the case of the dual magnetron sputtering process, the maximum power density per target can therefore be calculated as follows: Average output power of the DMS power supply of, for example, 20 KW, i.e. 10 KW per target, a fill factor of 0.5 and a target with a size of 83 cm×17 cm:

$$10 kW \div 83 cm \div 17 cm \div 0.5 = 14.17 W / {cm}^{2} .$$

In the method, a bias voltage applied to the substrate in the range of 125 V and 300 V has also proven to be advantageous. It is understood that the bias voltage is a negative voltage. In a refinement, the bias voltage applied to the substrate is a pulsed bias voltage which has a bias pulse frequency between 5 kHz and 80 kHz, preferably between 10 KHz and 40 kHz, particularly preferably between 20 KHz and 30 kHz. The bias voltage is preferably a bipolar bias voltage.

Furthermore, a bias current in the range of 10 A to 60 A has proven to be advantageous. If the bias voltage is set too low, this increases the proportion of amorphous Al₂O₃ in the Al₂O₃-layer, which ultimately leads to reduced hardness and a reduced modulus of elasticity of the coating. If, on the other hand, the bias voltage is set too high, this reduces the deposition rate. A bias current that is set too high can also lead to process instability.

According to a further refinement, the noble gas used in the gas mixture within the reaction chamber comprises argon (Ar) and/or krypton (Kr) and/or neon (Ne). Argon is preferred. However, mixtures of the aforementioned noble gases can also be used.

According to a further refinement, the at least one Al₂O₃-layer is deposited directly on the substrate material, wherein the substrate material is cemented carbide. Depositing the Al₂O₃-layer directly on cemented carbide has proven to be advantageous.

According to an alternative refinement, a plurality of layers are deposited on the substrate material, at least one layer of which is a metal oxide layer on which the at least one Al₂O₃-layer is directly deposited, wherein the metal oxide layer comprises an oxide of one or more of the metals Ti, Si, V, Zr, Mg, Fe, B, Gd, La and Cr.

A metal oxide layer comprising TiO₂ or consisting of TiO₂ has proven to be particularly advantageous. If the Al₂O₃-layer is deposited directly on such a TiO₂ layer, this also favors the formation of α-Al₂O₃-phase components in the Al₂O₃-layer.

In particular, Al₂O₃-layers having a layer thickness of ≥10 nm can be produced.

It is evident that the features referred to above and those yet to be explained below can be used not only in the respective combination indicated, but also in other combinations or individually, without departing from the spirit and scope of the present disclosure.

### BRIEF DESCRIPTION OF THE DRAWINGS

FIG. 1 shows a schematic representation of a coated tool part according to an embodiment;

FIG. 2 shows a schematic representation illustrating the layer structure of a coating according to a first embodiment;

FIG. 3 shows a schematic representation illustrating the layer structure of a coating according to a second embodiment;

FIG. 4 shows a schematic representation illustrating the layer structure of a coating according to a third embodiment;

FIG. 5 shows a schematic representation illustrating the layer structure of a coating according to a fourth embodiment;

FIG. 6 shows a first XRD diagram showing the results of a phase analysis using X-ray fine structure diffraction; and

FIG. 7 shows a second XRD diagram showing the results of a phase analysis using X-ray fine structure diffraction.

### DETAILED DESCRIPTION

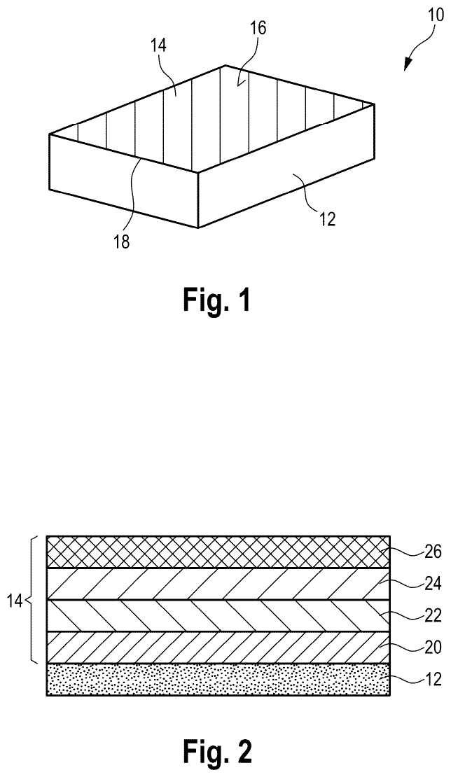

FIG. 1 shows a coated tool part in schematic form. The coated tool part is denoted therein in its entirety with the reference numeral 10.

The coated tool part can be an indexable insert, for example. In the present embodiment, the coated tool part 10 comprises a substrate 12 made of cemented carbide, which is coated with a coating 14 on part of its surface. Of course, the entire surface of the tool part 10 can also be coated.

In the present case, the coated surface may, for example, be a rake face 16 of an indexable cutting insert that has one or more cutting edges 18.

FIG. 2 schematically shows the layer structure of the coating 14 on the substrate 12.

According to the present embodiment, the coating 14 was carried out in a Hauzer HTC1000 coating system. A cemented carbide substrate 12 with a Co-content of 9.0 m % was used for the deposition of the coating 14. Furthermore, the substrate 12 has a mixed carbide content of approx. 1 m % and a WC content of approx. 90 m %.

According to this embodiment, the used cemented carbide substrate 12 has dimensions of 15 mm×15 mm×5 mm. Preferably, the cemented carbide substrate 12 has a hole (not shown) for holding it during deposition. One side surface of the substrate 12 has been polished.

It is understood that a large number of such substrates 12 were coated simultaneously in the coating system. The substrates 12 were thereby stored on a rotating substrate table. More precisely, the substrates 12 were arranged in towers, which are mounted on the substrate table and rotate together with it. A 3f-rotation was performed during the coating process.

The 2f-rotation describes a mounting method in which the substrates are rotated with both the substrate table and the towers on it. This creates a 2f-rotation around two parallel but not concentric axes. The 3f-rotation describes a mounting method in which the substrates are rotated both with the substrate table and the towers on it and also the skewers on which the substrates are mounted. This creates a 3f-rotation around three parallel but not concentric axes. The tool parts 10 were aligned in such a way that the coating thickness was measured on a rotating polished surface that was aligned parallel to the axes of rotation.

In the first embodiment shown in FIG. 2, a coating 14 with four individual layers was produced. According to the first embodiment, the coating 14 conmprises an AlTiN-layer 20, which was deposited directly on the cemented carbide substrate 12. A TiC-layer 22 was deposited on this AlTiN-layer 20. A TiO₂/TiOₓ-layer 24 was produced on the TiC-layer 22 by oxidation. An Al₂O₃-layer 26 was deposited on the TiO₂/TiOₓ-layer 24, which has both an α-Al₂O₃-phase fraction and a γ-Al₂O₃-phase fraction.

The AlTiN layer 20 was applied using HiPIMS sputtering. An AlTi 55/45 target consisting of 55 at % Al and 45 at % Ti was used for this purpose. A target power of 15 KW was set. The pulse on-time was 150 μs with a current control to 200 A and a starting voltage of 1400 V. The coil current was 4 A. An argon gas flow was set to 450 sccm. The total gas pressure in the reaction chamber was controlled to 420 mPa. Nitrogen (N₂) was used as the reactive gas for pressure control. The bias voltage was 80 V DC. The rotation of the substrate table was set to 3 rpm. The deposition time was 4 h 30 s. The deposition temperature was 550° C. The layer thickness of the AlTiN layer 20 produced in this way was approx. 1.2 μm.

Subsequently, the TiC layer 22 was also applied using HiPIMS sputtering. A Ti target was used for this. The target power was set to 15 KW. The pulse on-time was 60 μs with a current control to 500 A and a starting voltage of 1800 V. The coil current was set to 4 A. The bias voltage was set to 60 V DC. An argon gas flow of 500 sccm was used. Acetylene (C₂H₂) with a flow of 32.5 sccm was used as the reactive gas. The coating time was 3 h. The substrate temperature was set to 550° C. The rotation of the substrate table was set to 3 rpm. The TiC layer 22 has a layer thickness of approx. 0.4 μm.

Subsequently, the upper part of the TiC layer 22 was converted into the TiO₂/TiOₓ-layer 24 by means of an oxidation process. The oxidation of the TiC layer 22 to the TiO₂/TiOₓ-layer 24 was carried out at a substrate temperature of 600° C., an oxygen gas flow of 994 sccm and for a duration of 45 min. In this way, a TiO₂/TiOₓ-layer 24 having a layer thickness of approx. 0.1 μm was produced.

After the oxidation process, the Al₂O₃-layer 26 was applied to the existing layer composite using a dual magnetron sputtering process. Two aluminum targets were used for this. The two targets used were located on opposite sides of the reaction chamber. The pulse shape of the power supply used was in bipolar mode and rectangular. The power of the pulsed power supply was set to a constant 20 KW during deposition. The frequency of the power supply was 40 kHz. The duty cycle of the rectangular pulses was 50% (i.e. 50% positive voltage pulses and 50% negative voltage pulses). A gas mixture of argon and oxygen was used inside the reaction chamber. The argon gas flow was set to a constant 500 sccm. The oxygen gas flow was adjusted via the set operating point of the process control at 430 V. The oxygen gas flow was approx. 105 sccm. The total gas pressure was approx. 457 mPa. A negative bipolar pulsed bias voltage (substrate bias voltage) with a frequency of 30 kHz and an off time of 10 μs was applied to the substrates 12 during deposition. The level of the negative bias voltage was 175 V. The rotation of the substrate table was 2 rpm. The substrate temperature during deposition was 570° C. The coil current was set to 10 A. The deposition time was 2 h 10 min. The α-γ-Al₂O₃-layer 26 deposited in this way has a layer thickness of approx. 1.2 μm.

The deposition of the α-γ-Al₂O₃-layer on the TiO₂/TiOₓ-layer 24 has proven to be particularly advantageous, as this increased the formation of the α-Al₂O₃-phase components. Further tests by the applicant have shown that the TiO₂/TiOₓ-layer 24 should have a minimum layer thickness of 5 nm and the Al₂O₃-layer 26 should have a layer thickness of at least 10 nm.

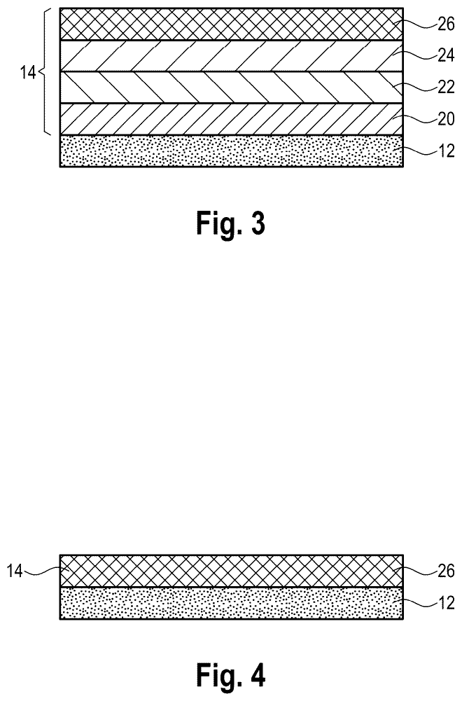

The layer structure of the coating 14 according to the second embodiment shown in FIG. 3 is principally similar to the layer structure according to the first embodiment shown in FIG. 2. Accordingly, the layers 20, 22, 24 were also produced by means of the same manufacturing processes using the same process parameters. For the sake of simplicity, these are therefore not repeated again.

In contrast to the first embodiment, during the deposition of the Al₂O₃-layer 26, the voltage was varied from 175 V to 125 V in the form of a time gradient. The bias current of about 21 A was slightly lower than in the first embodiment (about 26 A). The temporal variation of the bias voltage resulted in the Al₂O₃ layer 26 having a higher α-γ-Al₂O₃-phase fraction towards the upper end of the layer 26. The layer thickness of the α-γ-Al₂O₃-layer 26 was 1.4 μm according to the second embodiment.

In the third embodiment shown in FIG. 4, the Al₂O₃-layer 26 was also deposited using a dual reactive magnetron sputtering process. However, the Al₂O₃ layer 26 was deposited here directly on the cemented carbide substrate 12 (layers 20, 22, 24 therefore do not exist here). The deposition of the α-γ-Al₂O₃-layer 26 was carried out at a substrate temperature of approx. 550° C. in an argon-oxygen gas mixture. The power of the two aluminum targets was set to 20 kW. The total gas pressure during deposition was 454 mPa. A negative bias voltage of 200 V was applied to the substrates during the deposition process. The rotation of the substrate table was 2 rpm. The layer thickness of the α-γ-Al₂O₃-layer 26 was 0.8 μm according to the third embodiment.

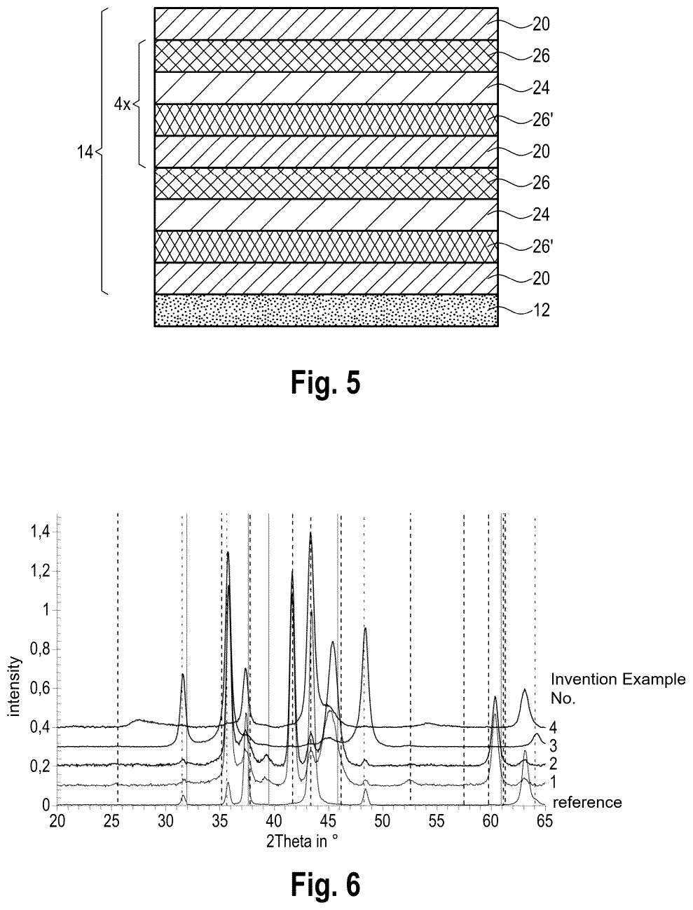

FIG. 5 shows a fourth embodiment of a coating 14. According to this fourth embodiment, the coating 14 has the following coating sequence starting from the substrate 12: An AlTiN layer 20 having a layer thickness of approx. 2000 nm, a thin Al₂O₃-layer 26′ having a layer thickness of approx. 15 nm, a TiO₂/TiOₓ-layer 24 having a layer thickness of approx. 60 nm, a α-γ-Al₂O₃-layer 26 having a layer thickness of approx. 500 nm and a four-layer composite, each of which has an AlTiN layer having a layer thickness of approx. 150 nm, an Al₂O₃-layer 26′ arranged above it having a layer thickness of 15 nm, a TiO₂/TiOₓ-layer having a layer thickness of 60 nm and a α-γ-Al₂O₃-layer 26 having a layer thickness of approx. 150 nm. According to the fourth embodiment, the uppermost layer of the coating 14 is an AlTiN layer 20 having a layer thickness of approximately 150 nm.

The α-γ-Al₂O₃-layers 26 contained in the coating 14 according to the fourth embodiment were produced in a similar manner as previously mentioned. The following tables summarize again the process parameters during the production of the α-γ-Al₂O₃-layers 26 for all four embodiments:

| Invention | Oxygen | Argon | Process | Bias |
|---|---|---|---|---|
| Example | gas flow | gas flow | temperature | voltage |
| No. | in sccm | in sccm | in ° C. | in V |
| 1 | ca. 105 | 500 | 570 | 175 |
| 2 | ca. 104 | 500 | 570 | 175 −> 125 |
| 3 | ca. 73 | 500 | 550 | 200 |
| 4 | ca. 104 | 500 | 570 | 175 |

| Invention | Bias | Bias | Bias | Table |
|---|---|---|---|---|
| Example | current | frequency | off-time | rotation |
| No | in A | in kHz | in μs | in rpm |
| 1 | ca. 26 | 30 | 10 | 2 |
| 2 | ca. 21 | 30 | 10 | 2 |
| 3 | ca. 24 | 20 | 1 | 2 |
| 4 | ca. 34 | 30 | 10 | 2 |

| Invention | Pulse | Pulse | DMS | Operating |
|---|---|---|---|---|
| Example | shape | frequency | power | point |
| No. | DMS | DMS in kHZ | in kW | in V |
| 1 | rectangular | 40 | 20 | 430 |
| 2 | rectangular | 40 | 20 | 430 |
| 3 | rectangular | 80 | 20 | 430 |
| 4 | rectangular | 40 | 20 | 430 |

| Invention Example | Deposition time | Coil current | total gas pressure |
|---|---|---|---|
| No. | in min | in A | in mPa |
| 1 | 130 | 10 | ca. 457 |
| 2 | 130 | 10 | ca. 455 |
| 3 | 180 | 10 | ca. 454 |
| 4 | 65 + 4*20 | 10 | ca. 465 |

As can be seen from the tables above, the total gas pressure in the four embodiments was selected in the range of 454 mPa-465 mPa. However, further tests by the applicant have shown that the total gas pressure can also be selected somewhat higher without the positive properties of the Al₂O₃-layer being lost. However, the total gas pressure should always be selected <1 Pa.

The process temperature was selected at 550° C. or 570° C. according to the four embodiments shown here. However, tests by the applicant have shown that other process temperatures in the range from 400° C. to 650° C. are also possible.

The coil current was selected at 10 A in each case. Tests by the applicant have shown that the coil current should generally be selected at ≥7 A to achieve the desired properties of the Al₂O₃-layer.

The following modifications to the above-mentioned embodiments are conceivable in principle: Instead of producing the TiO₂/TiOₓ-layers 24 via an oxidation process, a TiO₂ layer could also be produced by direct deposition. Furthermore, it should be noted with regard to the oxidized TiC-layers to TiO₂/TiOₓ-layers 24 that these may also have C as a further component, so that it could be a Ti—C—O layer.

It would also be conceivable to use a layer of WC—Co instead of TiO₂-layers 24 as sub-layers for the α-γ-Al₂O₃-layers 26.

The following table summarizes the analysis results of the coating properties of the four coatings 14 shown in FIGS. 2-5. For comparison, this table shows the coating properties of a reference coating consisting of an AlTiN-coating having a thickness of approx. 1.2 μm, which was deposited directly on the cemented carbide substrate 12.

| Invention | Layer | | red. modulus of | XRD Al₂O₃ |
|---|---|---|---|---|
| Example | thickness | Hardness H_{IT} | elasticity | phase |
| No. | in μm | in MPa | in GPa | analysis |
| reference | 1.2 | 26.3 | 543 | — |
| 1 | 2.9 | 34.5 | 431 | alpha + |
| | | | | gamma |
| 2 | 3.1 | 29.2 | 389 | alpha + |
| | | | | gamma |
| 3 | 0.8 | 36.3 | 464 | alpha + |
| | | | | gamma |
| 4 | 4.2 | 27.7 | 418 | alpha + |
| | | | | gamma |

The coating thickness was determined in each case by grinding a spherical cap with a steel ball with a diameter of 20 mm. The steel ball was used to grind a spherical cap. The rings visible in the spherical cap were then measured using an optical microscope. The measurements were carried out on the polished free surface of the carbide substrates 12.

The instrumented coating hardness H_{IT} and the instrumented modulus of elasticity E_{IT} were determined by nanoindentation using the Oliver-Pharr method. An NHT1 device from the manufacturer CSM Instruments with a Berkovich indenter made of diamond was used for the measurement. During the measurement, the maximum load was 10 mN, the loading time 30 s, the creep time 10 s and the unloading time 30 s. Loading and unloading curves were recorded. The hardness values and the values for the reduced modulus of elasticity (red. modulus of elasticity E_{IT}) were determined from these load and unloading curves using the Oliver-Pharr method. The measurements were carried out on the coating surface. A transverse contraction coefficient of 0.25 was used to determine the reduced modulus of elasticity.

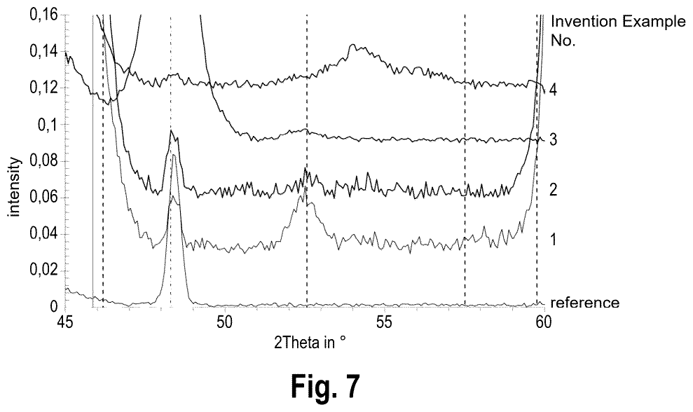

FIGS. 6 and 7 show the results of a phase analysis of the coating 14 using X-ray fine structure diffraction. The phase analysis was carried out using grazing incidence X-ray diffraction (GIXRD) at an angle of incidence of 1°. A diffractometer from Malvern Panalytical (Empyrean) with Cu K_{α} radiation at 40 kV and 40 mA was used. The measurements were carried out in line focus with a parallel beam via a mirror. A 2 mm mask, a ⅛° slit diaphragm to reduce the divergence and a 0.04 rad set point were used. A 0 D proportional detector with a 0.27° plate collimator was used for the measurement. For the measurements shown in FIG. 6, for example, a 2-theta measuring range of 20-65° with a step width of 0.07° and a counting width of 60 s was selected. The angle of incidence was kept constant at 1°. The resulting diffractograms were used for phase analysis. For better comparability, the background of the XRD diagrams was corrected, the diffractograms were normalized to the maximum intensity and a y-offset was added if necessary.

In addition to the reflections of the cemented carbide substrate 12 (hexagonal WC, space group P-6m2, space group no. 187, PDF no. 51-939 of the ICDD database, dot-dashed vertical line), several reflections of both α-Al₂O₃ (rhombohedral Al₂O₃, space group R-3c, space group no. 167, PDF No. 42-1468 of the ICDD database, dashed vertical lines) as well as from γ-Al₂O₃ (cubic Al₂O₃-space group Fd-3m, space group No. 227, PDF No. 10-425 of the ICDD database, vertical lines). For reasons of clarity, the TiO₂ and AlTiN phases were not marked in the diffractograms. The coatings exhibit the (024) reflex of α-Al₂O₃ at 2theta of approx. 52.559°. This demonstrates the existence of the α-Al₂O₃-phase in the coating 14. Furthermore, the γ-Al₂O₃-phase is also present.

It is to be understood that the foregoing is a description of one or more preferred exemplary embodiments of the invention. The invention is not limited to the particular embodiment(s) disclosed herein, but rather is defined solely by the claims below. Furthermore, the statements contained in the foregoing description relate to particular embodiments and are not to be construed as limitations on the scope of the invention or on the definition of terms used in the claims, except where a term or phrase is expressly defined above. Various other embodiments and various changes and modifications to the disclosed embodiment(s) will become apparent to those skilled in the art. All such other embodiments, changes, and modifications are intended to come within the scope of the appended claims.

As used in this specification and claims, the terms “for example,” “e.g.,” “for instance,” “such as,” and “like,” and the verbs “comprising,” “having,” “including,” and their other verb forms, when used in conjunction with a listing of one or more components or other items, are each to be construed as open-ended, meaning that the listing is not to be considered as excluding other, additional components or items. Other terms are to be construed using their broadest reasonable meaning unless they are used in a context that requires a different interpretation.

What is claimed is:

1. A method, comprising:
providing a tool part of a cutting tool as a substrate comprising a substrate material selected from the group consisting of cemented carbide, cermet, cubic boron nitride, polycrystalline diamond or high speed steel; and
coating the tool part with a coating comprising at least one aluminum oxide (Al₂O₃) containing Al₂O₃-layer having an alpha-Al₂O₃ phase fraction and a gamma-Al₂O₃ phase fraction,
wherein the Al₂O₃-layer is produced by a reactive magnetron sputtering process, and wherein in the reactive magnetron sputtering process:
at least one aluminum target is used;
a gas mixture is used which has a noble gas as a first component and oxygen (O₂) and/or a nitrogen oxide (NOₓ) as a second component as a reactive gas;
a total gas pressure <1 Pa is set;
a process temperature between 400° C. and 650° C. is set;
a maximum target power density≤100 W/cm² and a maximum target current ≤200 A is set; and
a magnetic field is generated using at least one solenoid coil, which is operated with a coil current ≥7 A.

2. The method according to claim 1, wherein the reactive magnetron sputtering process is a pulsed magnetron sputtering process.

3. The method according to claim 1, wherein the reactive magnetron sputtering process is a pulsed magnetron sputtering process with rectangular voltage pulses.

4. The method according to claim 3, wherein the rectangular voltage pulses are bipolar voltage pulses.

5. The method according to claim 3, wherein the rectangular voltage pulses have a pulse frequency between 10 KHz and 150 KHz.

6. The method according to claim 3, wherein the rectangular voltage pulses have a pulse frequency between 40 KHz and 80 KHz.

7. The method according to claim 1, wherein the reactive magnetron sputtering process is a dual magnetron sputtering process.

8. The method according to claim 1, wherein the reactive magnetron sputtering process is a dual magnetron sputtering process with two aluminum targets.

9. The method according to claim 1, wherein the total gas pressure is set <700 mPa.

10. The method according to claim 1, wherein the coil current is ≤10 A.

11. The method according to claim 1, wherein in the reactive magnetron sputtering process a time-averaged target power density of 3 W/cm² to 30 W/cm² is set.

12. The method according to claim 1, wherein in the reactive magnetron sputtering process a time-averaged target power density of 4 W/cm² to 20 W/cm² is set.

13. The method according to claim 1, wherein in the reactive magnetron sputtering process a bias voltage between 125 V and 300 V is applied to the substrate.

14. The method according to claim 13, wherein the bias voltage is a pulsed bias voltage having a bias pulse frequency between 5 kHz and 80 KHz.

15. The method according to claim 13, wherein a bias current is between 10 A and 60 A.

16. The method according to claim 1, wherein the noble gas comprises argon (Ar) and/or krypton (Kr) and/or neon (Ne).

17. The method according to claim 1, wherein the Al₂O₃-layer is deposited directly on the substrate material, and the substrate material is a cemented carbide.

18. The method according to claim 1, wherein a plurality of layers are deposited on the substrate material, at least one layer of which is a metal oxide layer on which the Al₂O₃-layer is directly deposited, wherein the metal oxide layer comprises an oxide of one or more of metals selected from the group consisting of Ti, Si, V, Zr, Mg, Fe, B, Gd, La and Cr.

19. The method according to claim 18, wherein the metal oxide layer comprises TiO₂.

20. A coated tool part of a cutting tool, said tool part comprising a substrate material selected from the group consisting of cemented carbide, cermet, cubic boron nitride, polycrystalline diamond or high speed steel, and a coating comprising at least one aluminum oxide (Al₂O₃) containing Al₂O₃-layer having an alpha-Al₂O₃ phase fraction and a gamma-Al₂O₃ phase fraction, wherein the Al₂O₃-layer is produced by the method according to claim 1.
